(19) United States
(12) Patent Application Publication
(10) Pub. No.: US 2025/0158628 A1
(43) Pub. Date: May 15, 2025

(54) ANALOG-TO-DIGITAL CONVERSION DEVICE

(71) Applicant: MACRONIX INTERNATIONAL CO., LTD., Hsinchu (TW)

(72) Inventors: Han-Wen HU, Zhubei City (TW); Yung-Chun LI, New Taipei City (TW); Chih-Chang HSIEH, Hsinchu City (TW); BO-RONG LIN, Taichung City (TW); Huai-Mu WANG, New Taipei City (TW); Chih-Huai SHIH, Hsinchu City (TW)

(21) Appl. No.: 18/736,681

(22) Filed: Jun. 7, 2024

Related U.S. Application Data
(60) Provisional application No. 63/548,544, filed on Nov. 14, 2023.

(51) Int. Cl. H03M 1/12; H03M 1/38; H03M 1/50

(52) U.S. Cl. CPC H03M 1/1245; H03M 1/38; H03M 1/50

(57) ABSTRACT

An analog-to-digital conversion device, includes the following elements. A sensing circuit, coupled to a bit line of a memory array, and used to sense a current in the bit line to generate a bit-sequence, the bit-sequence has a form of a thermometer code to represent an analog value. A latch logic circuit, including a plurality of latches and a plurality of logic circuits to form a page buffer of the memory array, and used to generate a bit-set according to the bit-sequence, the bit-set has a form of a binary code to represent a digital value. The latches and the logic circuits are used to perform a conversion process to convert the bit-sequence into the bit-set, and the conversion process has a bit width.

This application claims the benefit of U.S. provisional application Ser. No. 63/548,544, filed Nov. 14, 2023, the disclosure of which is incorporated by reference herein in its entirety.

### TECHNICAL FIELD

The present disclosure relates to an electronic device, and in particular, relates to an analog-to-digital conversion device.

### BACKGROUND

With the evolution of semiconductor technology, a memory array has an ability to perform in-memory computing (IMC) or in-memory searching (IMS). The results of in-memory computing and in-memory searching often require analog-to-digital conversion to obtain digital values. Furthermore, an analog-to-digital conversion device is relied upon to perform the analog-to-digital conversion.

Analog-to-digital conversion devices include several types which are commonly used: a flash analog-to-digital converter (flash ADC), a time-to-digital conversion (TDC) type of ADC, or a successive-approximation register (SAR) type of ADC. However, the above-mentioned analog-to-digital conversion devices have disadvantages in operation. For example, the flash ADC performs parallel input, hence it has a greater hardware circuit area. Moreover, when the TDC performs a conversion of the thermometer code and the binary code, it performs logical operations based on the flip-flop (DFF), hence its hardware circuit area is also great, and its operating time is long. In addition, the SAR type ADC must perform complex output storage and must additionally generate a reference voltage.

In view of the above issues, it is desirable to have an improved analog-to-digital conversion device which may achieve a smaller hardware circuit area and a shorter operating time, and may be adapted to a standard page buffer architecture of the memory array.

### SUMMARY

According to an embodiment of the present disclosure, an analog-to-digital conversion device is provided. The analog-to-digital conversion device includes the following elements. A sensing circuit, coupled to a bit line of a memory array, and used to sense a current in the bit line to generate a bit-sequence, the bit-sequence has a form of a thermometer code to represent an analog value. A latch logic circuit, including a plurality of latches and a plurality of logic circuits to form a page buffer of the memory array, and used to generate a bit-set according to the bit-sequence, the bit-set has a form of a binary code to represent a digital value. The latches and the logic circuits are used to perform a conversion process to convert the bit-sequence into the bit-set, and the conversion process has a bit width.

### BRIEF DESCRIPTION OF THE DRAWINGS

FIG. 1 is a circuit diagram of an analog-to-digital conversion device 1000 according to an embodiment of the present disclosure.

FIG. 2 is a circuit diagram of the sensing circuit 100 in FIG. 1.

FIG. 3A-1 is a schematic diagram illustrating the change of the voltage V_{SEN} of the node SEN of the sensing circuit 100 with respect to time t.

FIG. 3A-2 is a schematic diagram illustrating the changes of the voltage V_{SEN} of the node SEN and the voltage V_{Boost} of the node Boost.

FIG. 3B-1 is a schematic diagram illustrating the change of the voltage V_{SEN} of the node SEN with respect to time t when the analog-to-digital conversion device 1000 performs analog-to-digital conversion of two bits.

FIG. 3B-2 is a schematic diagram illustrating the changes of the voltage V_{SEN} of the node SEN and the voltage V_{Boost} of the node Boost when the analog-to-digital conversion device 1000 performs analog-to-digital conversion of two bits.

FIG. 4 is a circuit diagram of an analog-to-digital conversion device 1001 according to another embodiment of the present disclosure.

FIG. 5 is a schematic diagram illustrating the change of the voltage V_{SEN} of the node SEN with respect to time t when the analog-to-digital conversion device 1001 of FIG. 4 performs analog-to-digital conversion of three bits.

FIG. 6 is a circuit diagram of an analog-to-digital conversion device 1002 according to still another embodiment of the present disclosure.

FIG. 7A is a schematic diagram illustrating the change of the voltage V_{SEN} of the node SEN with respect to time t when the analog-to-digital conversion device 1002 of FIG. 6 performs analog-to-digital conversion of four bits.

FIG. 7B illustrates an adjustment method of the initial charge amount Q_{SEN} of the node SEN when the latch logic circuit 200 processes the bits O₀˜O₁₄ to generate the bits B₀˜B₃.

FIG. 7C is a schematic diagram illustrating the time consumption of performing input quantization at three time points according to the embodiment of FIG. 7A.

FIG. 8A is a schematic diagram illustrating the changes of the voltage V_{SEN} of the node SEN and the voltage V_{Boost} of the node Boost when the analog-to-digital conversion device 1002 of FIG. 6 utilizes a faster input quantization mechanism.

FIG. 8B is a schematic diagram illustrating the change of the voltage V_{SEN} of the node SEN with respect to time t when the analog-to-digital conversion device 1002 of FIG. 6 utilizes the faster input quantization mechanism.

FIG. 8C is a schematic diagram illustrating the time consumption of performing input quantization at a single time point according to the embodiment of FIG. 8B.

FIG. 9 is a circuit diagram of an analog-to-digital conversion device 1003 according to yet another embodiment of the present disclosure.

FIG. 10 is a schematic diagram illustrating the change of the voltage V_{SEN} of the node SEN with respect to time t when the analog-to-digital conversion device 1003 of FIG. 9 performs analog-to-digital conversion of five bits.

FIG. 11 illustrates an adjustment method of the initial charge amount Q_{SEN} of the node SEN when the latch logic circuit 200 of this embodiment processes the bits O₀˜O₁₄ to generate the bits B₀˜B₃.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

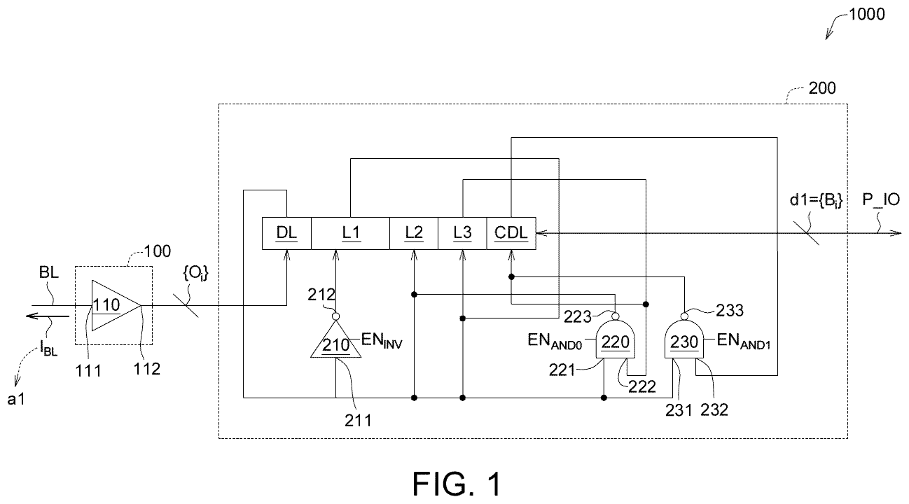

FIG. 1 is a circuit diagram of an analog-to-digital conversion device 1000 according to an embodiment of the present disclosure. As shown in FIG. 1, the analog-to-digital conversion device 1000 is coupled to one bit line BL of the bit lines of the memory array (the memory array is not shown in FIG. 1). The memory array is, for example, an array of NAND flash or an array of NOR flash, etc. In the memory array, a memory string corresponding to the bit line BL performs in-memory computing (IMC) or in-memory searching (IMS), and the bit line BL generates a current I_{BL} to represent an operation result or a searching result. The current I_{BL} has an analog value a1.

The analog-to-digital conversion device 1000 includes a sensing circuit 100 and a latch logic circuit 200. The sensing circuit 100 is coupled to the bit line BL, and the sensing circuit 100 senses the current I_{BL} and generates a sensing result. The sensing result may be represented as a bit-sequence {Oi} to reflect the analog value a1 of the current I_{BL}. The bit-sequence {Oi} includes several bits O₀, O₁, O₂, etc.

The analog-to-digital conversion device 1000 is used to perform analog-to-digital conversion to convert the analog value a1 of the current I_{BL} into a digital value d1. The digital value d1 may be represented as a bit-set {Bi}. The bit-set {Bi} includes several bits B₁, B₂, etc. The analog-to-digital conversion device 1000 of this embodiment performs analog-to-digital conversion of two bits (i.e., the bit width is equal to “two”) according to a mechanism of time-to-digital conversion (TDC), and the generated digital value d1 includes two bits B₁ and B₀.

The sensing circuit 100 includes a sensing amplifier (SA) 110. The input end 111 of the sensing amplifier 110 is coupled to the bit line BL. The output end 112 of the sensing amplifier 110 is coupled to the latch logic circuit 200. The latch logic circuit 200 is coupled to the output end 112 of the sensing amplifier 110. The latch logic circuit 200 is used to process the sensing result generated by the sensing circuit 100, so as to convert the analog value a1 represented by the bit-sequence {Oi} into the digital value d1 represented by the bit-set {Bi}. Furthermore, the latch logic circuit 200 transmits the generated digital value d1 to an external circuit through a data input/output path P_IO (the external circuit is not shown in FIG. 1). In one example, the external circuit is an accumulator, and the data input/output path P_IO is disposed corresponding to the bit line BL.

More specifically, the latch logic circuit 200 has a circuit architecture of a “page buffer”. The page buffer is adapted to the architecture and operations of the memory array. The latch logic circuit 200 includes a latch DL, latches L1˜L3 and a latch CDL for performing latch function. Furthermore, the latch logic circuit 200 includes several logic circuits to perform logic operations, such as an inverter 210, a NAND gate 220 and a NAND gate 230. The latch DL is coupled to the output end 112 of the sensing amplifier 110 to receive and store the bit-sequence {Oi} generated by the sense circuit 100. The latch CDL outputs the bit-set {Bi} through the data input and output path P_IO.

In this embodiment, the input end 211 of the inverter 210, the input end 221 of the NAND gate 220 and the input end 231 of the NAND gate 230 are jointly coupled to the latch DL, the latch L2 and the latch. The other input end 222 of the NAND gate 220 is coupled to the latch L3, and the other input end 232 of the NAND gate 230 is coupled to the latch CDL. Furthermore, the output end 212 of the inverter 210 is coupled to the latch L1, and the output end 223 of the NAND gate 220 and the output end 233 of the NAND gate 230 are jointly coupled to the latch CDL. Furthermore, the inverter 210, the NAND gate 220 and the NAND gate 230 respectively receive an enable signal EN_{INV}, an enable signal EN_{AND0} and an enable signal EN_{AND1}.

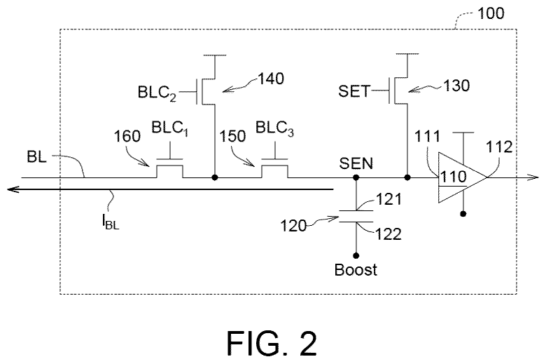

FIG. 2 is a circuit diagram of the sensing circuit 100 in FIG. 1. As shown in FIG. 2, the sensing circuit 100 includes a sensing amplifier 110, four transistors 130, 140, 150 and 160, and a capacitor 120. The current I_{BL} of bit line BL flows through transistors 150 and 160. The transistor 160 is coupled to the transistor 150 in series, and the transistor 150 is connected to the input end 111 of the sensing amplifier 110. One end of the transistor 140 is coupled between the transistors 150 and 160. Transistor 130 has a gate voltage SET, transistor 140 has a gate voltage BLC₂, transistor 150 has a gate voltage BLC₃, and transistor 160 has a gate voltage BLC₁.

One end 121 of the capacitor 120, one end of the transistor 130 and the input end 111 of the sensing amplifier 110 are jointly coupled to a node SEN. The node SEN has a voltage V_{SEN}. The voltage V_{SEN} may be referred to as the “first node voltage”. The other end 122 of the capacitor 120 is coupled to a node Boost. The node Boost has a voltage V_{Boost}. The voltage V_{Boost} may be referred to as the “second node voltage”.

The sensing circuit 100 may set the voltage V_{SEN} of the node SEN as an initial voltage V_{SEN01}. Furthermore, the sensing circuit 100 may set the node SEN to have an initial charge amount Q_{SEN}. The initial charge amount Q_{SEN} is equal to the initial voltage V_{SENO1} multiplied by an equivalent capacitance C_{SEN} of the node SEN, as shown in equation (1-1).

$${Q}_{SEN} = {V}_{SEN 01} \times {C}_{SEN} \qquad ( 1 - 1 )$$

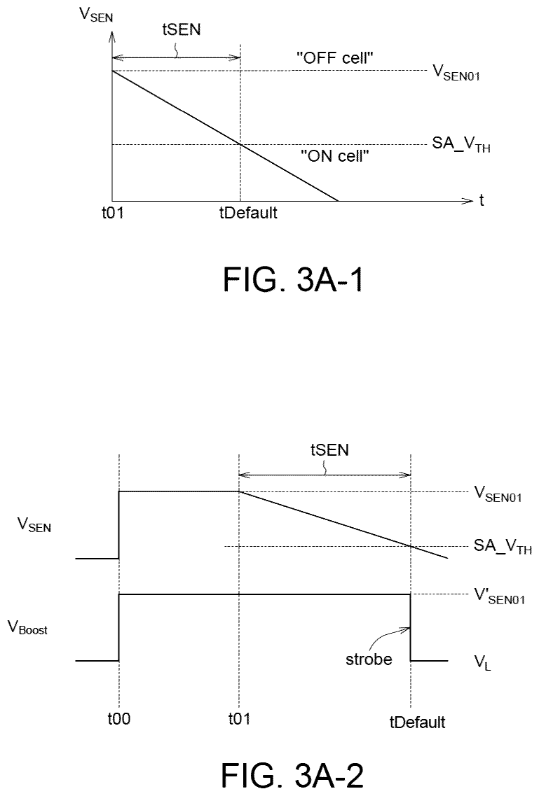

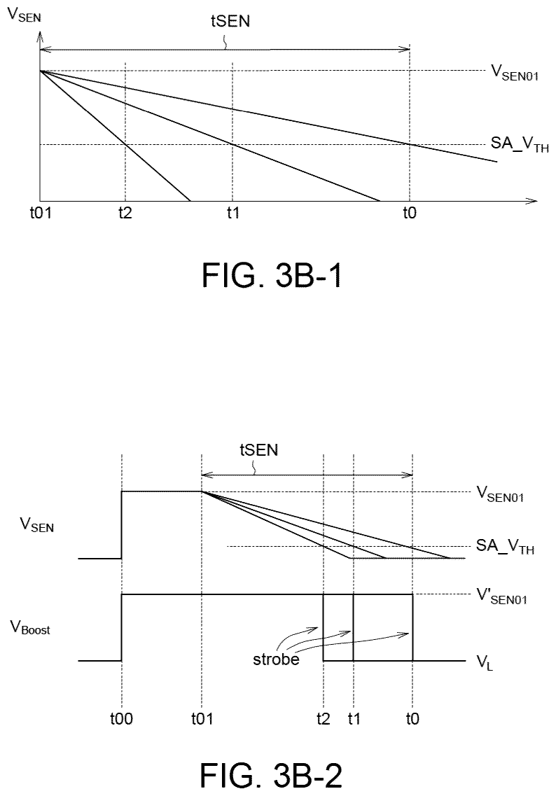

FIG. 3A-1 is a schematic diagram illustrating the change of the voltage V_{SEN} of the node SEN of the sensing circuit 100 with respect to time t. Please refer to both FIGS. 2 and 3A-1. If the sensing circuit 100 is in a turned-off state (referred to as an “OFF cell”), the sensing circuit 100 does not allow any current to flow, hence the node SEN will not discharge, and the voltage V_{SEN} of the node SEN remains as Initial voltage V_{SEN01}. On the contrary, if the sensing amplifier 110 is in a turned-on state (referred to as an “ON cell”), the current I_{BL} of the bit line BL may flow through the sense circuit 100, and the node SEN may be discharged by the current I_{BL}, causing the voltage V_{SEN} of the node SEN to decrease.

The sensing amplifier 110 has a threshold voltage SA_V_{TH}. The sensing amplifier 110 may include a differential amplifier, inside the sensing amplifier 110 (the differential amplifier is not shown in FIG. 2). The threshold voltage SA_V_{TH} of the sensing amplifier 110 is, for example, a reference voltage of one input end of the differential amplifier. In the turned-on state “ON cell” of the sensing amplifier 110, the voltage V_{SEN} of the node SEN continues to decrease with time t, and the voltage V_{SEN} of the node SEN decreases to the threshold voltage SA_V_{TH} at time point tDefault The period tSEN from time point t01 to time point tDefault may be referred to as an “execution period”.

FIG. 3A-2 is a schematic diagram illustrating the changes of the voltage V_{SEN} of the node SEN and the voltage V_{Boost} of the node Boost. Please refer to both FIGS. 2 and 3A-2, In an initial stage of operation of the sensing circuit 100, the sensing circuit 100 charges the node SEN, so that the voltage V_{SEN} of the node SEN increases to the initial voltage V_{SEN01} at time point t00. Through the coupling effect of the capacitor 120, the voltage V_{Boost} of the node Boost also increases to the initial voltage V′_{SEN01} at the time point t00.

Then, the node SEN is discharged by the current I_{BL} of the bit line BL, and the voltage V_{SEN} of the node SEN starts to decrease from the time point t01, and decreases to the threshold voltage SA_V_{TH} of the sensing amplifier 110 at the time point tDefault. During the execution period tSEN between time point t01 and time point tDefault, the operation of the sensing circuit 100 may be referred to as “bit line toggling (BL toggling)”.

The voltage V_{Boost} of the node Boost decreases to a low voltage V_{L} at time point tDefault. Through the coupling effect of the capacitor 120, the voltage V_{SEN} of the node SEN also further decreases. The operation in which the voltage V_{Boost} decreases to the low voltage V_{L} at the time point tDefault may be referred to as a “strobe” of the sensing amplifier 110.

When the sensing amplifier 110 performs the strobe at time point tDefault, the sensing amplifier 110 generates a corresponding bit Oᵢ according to the relationship between the voltage V_{SEN} and the threshold voltage SA_V_{TH}. If the voltage of node SEN at time point tDefault is greater than the threshold voltage SA_V_{TH} (as shown in equation (1-2)), the bit Oᵢ generated by the sensing amplifier 110 is a logic value “0”. In which, the current I_{BL} multiplied by execution time tSEN is equal to a charge amount difference ΔQ which is discharged by node SEN. The charge amount difference ΔQ divided by the equivalent capacitance C_{SEN} of the node SEN is equal to a voltage difference ΔV which is discharged by the node SEN. The initial voltage V_{SENO1} minus the voltage difference ΔV is equal to the voltage of node SEN at time point tDefault.

$${SA\_V}_{TH} < {V}_{SEN 01} - ( {I}_{BL} \times tSEN ) / {C}_{SEN} \qquad ( 1 - 2 )$$

On the contrary, if the voltage of node SEN at time point tDefault is less than the threshold voltage SA_V_{TH} (as shown in equation (1-3)), then the bit Oᵢ generated by the sensing amplifier 110 is a logic value “1”.

$${SA\_V}_{TH} > {V}_{SEN 01} - ( {I}_{BL} \times tSEN ) / {C}_{SEN} \qquad ( 1 - 3 )$$

FIG. 3B-1 is a schematic diagram illustrating the change of the voltage V_{SEN} of the node SEN with respect to time t when the analog-to-digital conversion device 1000 performs analog-to-digital conversion of two bits. FIG. 3B-2 is a schematic diagram illustrating the changes of the voltage V_{SEN} of the node SEN and the voltage V_{Boost} of the node Boost when the analog-to-digital conversion device 1000 performs analog-to-digital conversion of two bits. Please refer to both FIGS. 2, 3B-1 and 3B-2, in order to perform analog-to-digital conversion of two bits, the sensing circuit 100 sets three time points t2, t1 and t0 to perform sequential input quantization, and the time points t2, t1 and t0 may be referred to as “sensing time points”. The sensing circuit 100 performs strobe operations at time points t2, t1 and t0 to generate three bits O₂, O₁ and O₀ respectively. The sensing circuit 100 performs bit line recovery operation on the bit line BL at time points t2, t1 and t0 respectively.

For example, the sensing circuit 100 discharges the node SEN by the current I_{BL} of the bit line BL, so that the voltage V_{SEN} starts to decrease from the time point t01, and decreases to the threshold voltage SA_V_{TH} of the sensing amplifier 110 at the time point t2, and performs a strobe operation at the time point t2 to generate bit O₂. At time point t2, the charge amount difference ΔQ which is discharged by node SEN, is equal to the current I_{BL} multiplied by a time difference between time point t2 and time point t01. Similarly, the sensing circuit 100 performs a strobe operation at time point t1 to generate bit O₁. At time point t1, the charge amount difference ΔQ which is discharged by node SEN, is equal to the current I_{BL} multiplied by the time difference between time point t1 and time point t01. Furthermore, the sensing circuit 100 performs a strobe operation at time point t0 to generate bit O₀. The charge amount difference ΔQ which is discharged by node SEN at time point t0, is equal to the current I_{BL} multiplied by the time difference between time point t0 and time point t01.

The three bits O₂, O₁ and O₀ generated by the sensing circuit 100 at time points t2, t1 and t0 have a form of a thermometer code. The several latches and several logic circuits of the latch logic circuit 200 are used to perform conversion process to convert the bits O₂, O₁ and O₀ of the thermometer code into two bits B₁ and B₀ of the binary code, so as to form the digital value d1. That is, the latch logic circuit 200 performs a conversion process to convert the bit-sequence {Oᵢ} of the thermometer code into the bit-set {Bi} of the binary code. The bit width of the conversion process performed by the latch logic circuit 200 is equal to the bit width of the analog-to-digital conversion performed by the analog-to-digital conversion device 1000. The bit width of this embodiment is equal to “two”.

TABLE 1-1

| thermometer code | | | Binary code | | Decimal |
|---|---|---|---|---|---|
| O₂ | O₁ | O₀ | B₁ | B₀ | value |
| 0 | 0 | 0 | 0 | 0 | 0 |
| 0 | 0 | 1 | 0 | 1 | 1 |
| 0 | 1 | 1 | 1 | 0 | 2 |
| 1 | 1 | 1 | 1 | 1 | 3 |

Table 1-1 is a truth table for the conversion of the bits O₂, O₁ and O₀ of the thermometer code into the bits B₁ and B₀ of the binary code. For example, when bits O₂, O₁ and O₀ are “0,0,0”, they are converted into bits B₁ and B₀ as “0,0”. When bits O₂, O₁ and O₀ are “0,0,1”, they are converted into bits B₁ and B₀ as “0, 1”, etc. According to Table 1-1, a “true value conversion” of bits O₂, O₁ and O₀ and bits B₁ and B₀ may be obtained, such as equation (2-1) and equation (2-2).

$${B}_{1} = {O}_{1} \qquad ( 2 - 1 )$$

$${B}_{0} = \overline{{O}_{0} \& \overline{{O}_{1}} \& {O}_{1} \& {O}_{2}} \qquad ( 2 - 2 )$$

Please refer to FIG. 1 again, the inverter 210, NAND gate 220 and NAND gate 230 of the latch logic circuit 200 are used to perform the true value conversion between the thermometer code and the binary code in Table 1-1. More specifically, the inverter 210, the NAND gate 220 and the NAND gate 230 are respectively enabled to perform logical operations in different operating cycles according to the enable signals EN_{INV}, EN_{AND0} and EN_{AND1}, and cooperate with latches DL, L1, L2, L3 and CDL to convert the bits O₂, O₁ and O₀ of the thermometer code into the bits B₁ and B₀ of the binary code according to equations (2-1) and (2-2). Please refer to Table 1-2 and Table 1-3 for the logic operations of the latch logic circuit 200. Firstly, in the operating period “Cycle 1”, the following operations are performed: (1) The bit O₂ obtained at time point t2 is stored in the latch DL. (2) The bit O₂ stored in the latch DL is transferred to the latch L3.

Then, in the next operating period “Cycle 2”, the following operations are performed: (1) The bit O₁ obtained at time point t1 is stored in the latch DL. (2) The bit O₁ stored in the latch DL and the bit O₂ stored in the latch L3 are performed with an “NAND” operation by the NAND gate 220 to obtain O̅₂̅&̅O̅₁̅. And, the operation result O̅₂̅&̅O̅₁̅ is stored in the latch L3. (3) The inverter 210 inverts the bit O₁ stored in the latch DL to O̅₁̅ and stores it in the latch L1. (4) The bit O₁ stored in the latch DL is transferred to the latch L2. (5) The O̅₂̅&̅O̅₁̅ stored in latch L3 is transferred to latch CDL.

Then, in the next operating cycle “Cycle 3”, the following operations are performed: (1) The bit O₁ stored in the latch DL is transferred to the latch L3. (2) The bit O₀ obtained at time point t1 is stored in the latch DL. (3) The bit O₀ stored in the latch DL and the bit 01 stored in the latch L3 perform an “NAND” operation through the NAND gate 220 to obtain O̅₁̅&̅O̅₀̅, and the operation result O̅₁̅&̅O̅₀̅ is stored in latch L3. (4) The O̅₁̅&̅O̅₀̅ stored in the latch CDL and the O̅₁̅&̅O̅₀̅ stored in the latch L3 perform an “NAND” operation through the NAND gate 230 to obtain O̅₀̅&̅O̅₁̅&̅O̅₁̅&̅O̅₂̅ and stored to latch CDL.

TABLE 1-2

| Cycle | DL | L1 | L2 | L3 | CDL |
|---|---|---|---|---|---|
| 1 | O₂ | | | O₂ | |
| 2 | O₂ → O₁ | O̅₁̅ | O₁ | $\text{} \begin{matrix}{O}_{2} \to \\ \overline{{O}_{2} \& {O}_{1}}\end{matrix}$ | O̅₂̅&̅O̅₁̅ |
| 3 | O₁ → O₀ | O̅₁̅ | O₁ | $\text{} \begin{matrix}\overline{{O}_{2} \& {O}_{1}} \to \\ \overline{{O}_{1}} \to \\ \overline{{O}_{0} \& \overline{{O}_{1}}}\end{matrix}$ | $\text{} \begin{matrix}\overline{{O}_{2} \& {O}_{1}} \to \\ \overline{{O}_{0} \& \overline{{O}_{1}} \& {O}_{1} \& {O}_{2}}\end{matrix}$ |

TABLE 1-3

| Cycle | | | | |
|---|---|---|---|---|
| 1 | L3 = | | | |
| | DL | | | |
| 2 | L3 = | CDL= | L1 = | L2 = |
| | (L3)NAND(DL) | L3 | INV(DL) | DL |
| 3 | L3 = | L3 = | CDL = | |
| | DL | (L3)NAND(DL) | (CDL)NAND(L3) | |

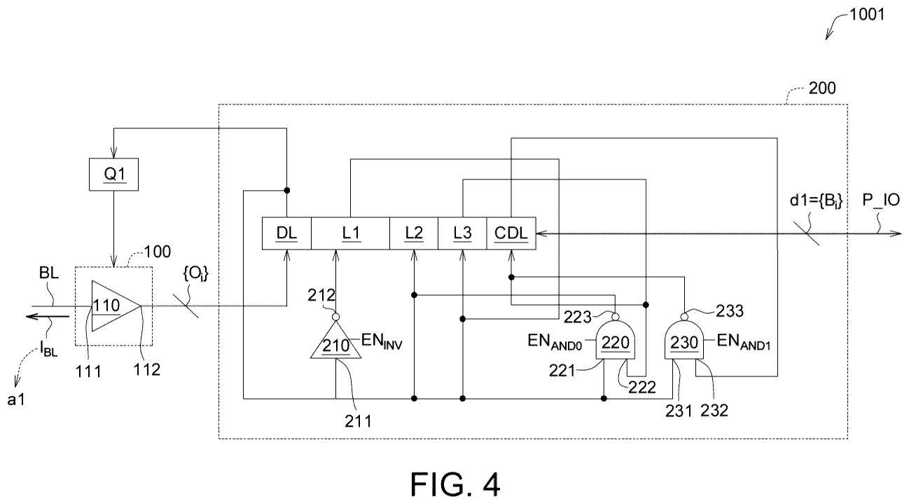

FIG. 4 is a circuit diagram of an analog-to-digital conversion device 1001 according to another embodiment of the present disclosure. The analog-to-digital conversion device 1001 of this embodiment is used to perform analog-to-digital conversion of three bits (i.e., the bit width is equal to “three”). The generated digital value d1 may include three bits B₂, B₁, and B₀. Compared with the analog-to-digital conversion device 1000 in FIG. 1, the analog-to-digital conversion device 1001 of this embodiment further includes a latch element Q1. The latch element Q1 is coupled to the latch DL of the latch logic circuit 200 and the sensing circuit 100. The latch element Q1 is used to set the initial charge amount Q_{SEN} of the node SEN of the sensing circuit 100.

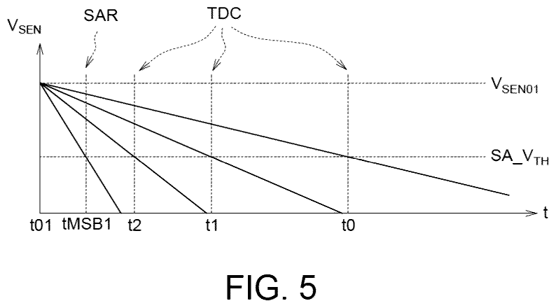

FIG. 5 is a schematic diagram illustrating the change of the voltage V_{SEN} of the node SEN with respect to time t when the analog-to-digital conversion device 1001 of FIG. 4 performs analog-to-digital conversion of three bits. Please refer to both FIGS. 4 and 5, the sensing circuit 100 of this embodiment sets four time points tMSB1, t2, t1 and t0 to perform sequence input quantization. More specifically, according to the mechanism of the successive-approximation register (SAR), the analog-to-digital conversion device 1001 generates bit B₂ of the most significant bit (MSB) at the time point MSB1. After sensing at time point tMSB1, the sensing circuit 100 sets the initial charge amount Q_{SEN} of the node SEN as an equivalent charge amount Q or an equivalent charge amount 2Q, through the latch element Q1. In an example, the equivalent capacitance C_{SEN} of the node SEN may be set as 2 times, or the voltage difference ΔV with which the node SEN is discharged may be set as 2 times. Alternatively, the equivalent capacitance C_{SEN} may be set as 1.4 times, or the voltage difference ΔV for discharging may be set as 1.4 times.

Then, according to the mechanism of TDC, the analog-to-digital conversion device 1001 generates the two bits B₁ and B₀ of the least significant bits (LSB) at time points t2, t1, and t0.

TABLE 2-1

| Thermometer code | | | | | | | Binary code | | | Decimal |
|---|---|---|---|---|---|---|---|---|---|---|
| O6 | O5 | O4 | O3 | O2 | O1 | O0 | B2 | B1 | B0 | value |
| N/A | N/A | N/A | 0 | 0 | 0 | 0 | 0 | 0 | 0 | 0 |
| N/A | N/A | N/A | 0 | 0 | 0 | 1 | 0 | 0 | 1 | 1 |
| N/A | N/A | N/A | 0 | 0 | 1 | 1 | 0 | 1 | 0 | 2 |
| N/A | N/A | N/A | 0 | 1 | 1 | 1 | 0 | 1 | 1 | 3 |
| 0 | 0 | 0 | 1 | N/A | N/A | N/A | 1 | 0 | 0 | 4 |
| 0 | 0 | 1 | 1 | N/A | N/A | N/A | 1 | 0 | 1 | 5 |
| 0 | 1 | 1 | 1 | N/A | N/A | N/A | 1 | 1 | 0 | 6 |
| 1 | 1 | 1 | 1 | N/A | N/A | N/A | 1 | 1 | 1 | 7 |

Table 2-1 is a truth table for converting the bits O₀˜O₆ of the thermometer code into the bits B₀˜B₂ of the binary code. According to Table 2-1, the conversion relationship between bits O₀˜O₆ and bits B₀˜B₂ may be obtained, such as Equation (3-1)˜Equation (3-3).

$${B}_{2} = {O}_{3} \qquad ( 3 - 1 )$$

$${B}_{1} = {O}_{1} ( or , {B}_{1} = {O}_{5} ) \qquad ( 3 - 2 )$$

$${B}_{0} = \overline{{O}_{0} \& \overline{{O}_{1}} \& {O}_{1} \& {O}_{2}} ( or , {B}_{0} = \overline{{O}_{4} \& \overline{{O}_{5}} \& {O}_{6} \& {O}_{5}} ) \qquad ( 3 - 3 )$$

The inverter 210, NAND gate 220 and NAND gate 230 of the latch logic circuit 200 perform logical operations to convert the bits O₀˜O₆ of the thermometer code into bits B₀˜B₂ of the binary code. Please refer to Table 2-2 and Table 2-3 for the logic operations of the latch logic circuit 200. Firstly, in the operating period “Cycle 1”, the following operations are performed: (1) The bit O₃ obtained at time point t3 is stored in the latch DL, and the bit O₃ is transferred to the latch CDL. (2) Latch element Q1 stores bit O₃ to replace the originally stored logic value “1”.

Then, in the operating period “Cycle 2”, the following operations are performed: (1) The bit O₃ stored in the latch DL is transferred to the latch L3.

Then, in the next operating period “Cycle 3”, the following operations are performed: (1) The bit O₁ stored in the latch DL and the bit O₂ stored in the latch L3 are performed with an “NAND” operation through the NAND gate 220 to obtain O̅₂̅&̅O̅₁̅. The operation result O̅₂̅&̅O̅₁̅ is stored in the latch L3. (2) The O̅₂̅&̅O̅₁̅ stored in latch L3 is transferred to latch CDL. (3) The inverter 210 inverts the bit O₁ stored in the latch DL to O̅₁̅ and stores it in the latch L1. (4) The bit O₁ stored in the latch DL is transferred to the latch L2.

Then, in the next operating cycle “Cycle 4”, the following operations are performed: (1) O₀ stored in latch L1 is transferred to latch L3. (2) The O₀ stored in the latch L3 and the O̅₁̅ stored in the latch DL are performed with an “NAND” operation by the NAND gate 220 to obtain O₀ & O̅₁̅, and store it in the latch L3. (3) The O₀ & O̅₁̅ stored in the latch L3 and the O̅₂̅&̅O̅₁̅ stored in the latch CDL are performed with an “NAND” operation by the NAND gate 220 to obtain O̅₀̅&̅O̅₁̅&̅O̅₁̅&̅O̅₂̅.

TABLE 2-2

| Cycle | DL | L1 | L2 | Q1 | L3 | CDL |
|---|---|---|---|---|---|---|
| 1 | O₃ | | | 1 → | | O₃ |
| | | | | O₃ | | |
| 2 | O₃ → | | | O₃ | O₂ | O₃ |
| | O₂ | | | | | |
| 3 | O₂ → O₁ | $\overline{{O}_{2}} \to \overline{{O}_{1}}$ | O₁ | O₃ | ${O}_{2} \to \overline{{O}_{1} \& {O}_{2}}$ | O̅₁̅ &̅ O̅₂̅ |
| 4 | O₁ → O₀ | O̅₁̅ | O₁ | O₃ | $\overline{{O}_{1} \& {O}_{2}} \to \overline{{O}_{1}} \to \overline{{O}_{0} \& \overline{{O}_{1}}}$ | $\overline{{O}_{1} \& {O}_{2}} \to \overline{{O}_{0} \& \overline{{O}_{1}} \& {O}_{1} \& {O}_{2}}$ |

TABLE 2-3

| Cycle | | | | |
|---|---|---|---|---|
| 1 | Q1 = | | | |
| | DL | | | |
| 2 | L3 = | | | |
| | DL | | | |
| 3 | L3 = | CDL = | L1 = | L2 = |
| | (L3)NAND(DL) | L3 | INV(DL) | DL |
| 4 | L3 = | L3 = | CDL = | |
| | L1 | (L3)NAND(DL) | (CDL)NAND(L3) | |

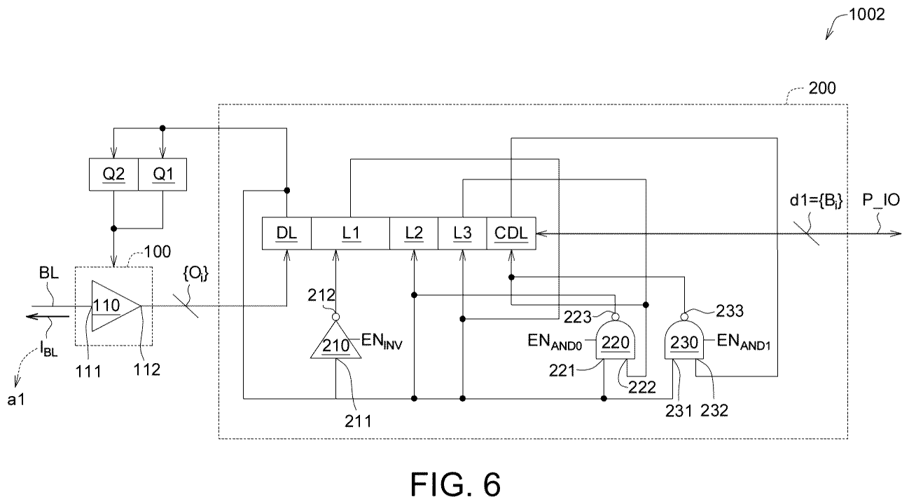

FIG. 6 is a circuit diagram of an analog-to-digital conversion device 1002 according to still another embodiment of the present disclosure. The analog-to-digital conversion device 1002 of this embodiment is used to perform analog-to-digital conversion of four bits (i.e., the bit width is equal to “four”). The generated digital value d1 may include four bits B₃, B₂, B₁ and B₀. Compared with the analog-to-digital conversion device 1001 in FIG. 4, the 10 analog-to-digital conversion device 1002 of this embodiment further includes another latch element Q2. The latch elements Q2 and Q1 are both coupled to the latch DL of the latch logic circuit 200 and the sensing circuit 100. The latch elements Q2 and Q1 are used to set the initial charge amount Q_{SEN} of the node SEN of the sensing circuit 100.

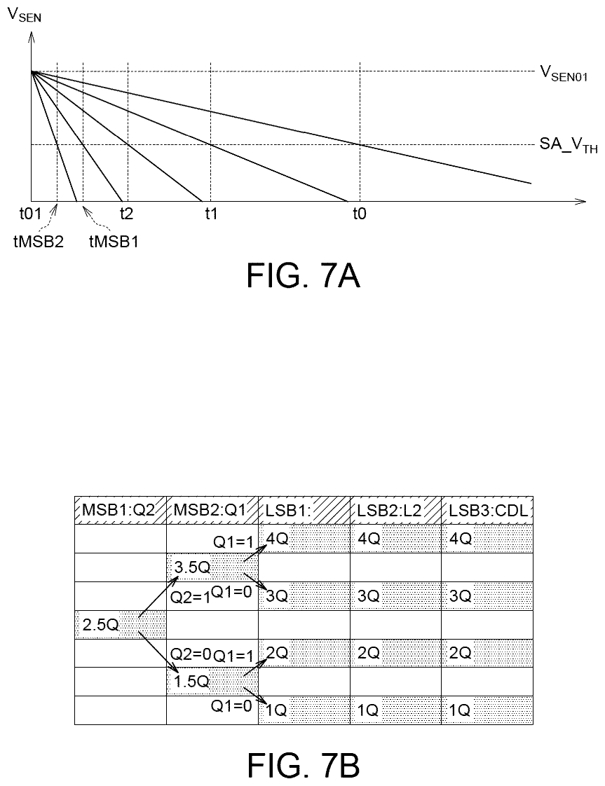

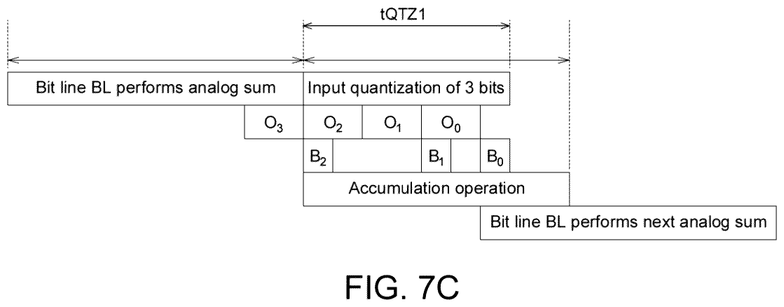

FIG. 7A is a schematic diagram illustrating the change of the voltage V_{SEN} of the node SEN with respect to time t when the analog-to-digital conversion device 1002 of FIG. 6 performs analog-to-digital conversion of four bits. Please refer to both FIGS. 6 and 7A, the sensing circuit 100 of this embodiment sets five time points tMSB2, tMSB1, t2, t1 and t0 to perform sequential input quantization. The initial charge amount Q_{SEN} of the node SEN is set as an equivalent charge amount 2.5Q by the latch elements Q2 and Q1. According to the mechanism of SAR, the analog-to-digital conversion device 1002 generates the bit B₃ of the MSB at time point tMSB2. Then, it is selectively adjusted as equivalent charge amounts of 3.5Q or 1.5Q, and the bit B₂ of the MSB is generated at time point tMSB1 according to the mechanism of SAR. Then, the initial charge amount Q_{SEN} of the node SEN is set as an equivalent charge amount Q through the latch elements Q1 and Q2. Then, it is selectively adjusted as equivalent charge amounts of 2Q, 3Q or 4Q. According to the mechanism of TDC, the analog-to-digital conversion device 1002 generates the two bits B₁ and B₀ of the LSB at time points t2, t1 and t0 respectively. Table 3-1 is a truth table for the bits O₀˜O₁₄ of the thermometer code to convert into the bits B₀˜B₃ of the binary code.

TABLE 3-1
Thermometer code

| O₁₄ | O₁₃ | O₁₂ | O₁₁ | O₁₀ | O₉ | O₈ | O₇ | O₆ | O₅ |
|---|---|---|---|---|---|---|---|---|---|
| N/A | N/A | N/A | N/A | N/A | N/A | N/A | 0 | N/A | N/A |
| N/A | N/A | N/A | N/A | N/A | N/A | N/A | 0 | N/A | N/A |
| N/A | N/A | N/A | N/A | N/A | N/A | N/A | 0 | N/A | N/A |
| N/A | N/A | N/A | N/A | N/A | N/A | N/A | 0 | N/A | N/A |
| N/A | N/A | N/A | N/A | N/A | N/A | N/A | 0 | 0 | 0 |
| N/A | N/A | N/A | N/A | N/A | N/A | N/A | 0 | 0 | 0 |
| N/A | N/A | N/A | N/A | N/A | N/A | N/A | 0 | 0 | 1 |
| N/A | N/A | N/A | N/A | N/A | N/A | N/A | 0 | 1 | 1 |
| N/A | N/A | N/A | 0 | 0 | 0 | 0 | 1 | N/A | N/A |
| N/A | N/A | N/A | 0 | 0 | 0 | 1 | 1 | N/A | N/A |
| N/A | N/A | N/A | 0 | 0 | 1 | 1 | 1 | N/A | N/A |
| N/A | N/A | N/A | 0 | 1 | 1 | 1 | 1 | N/A | N/A |
| 0 | 0 | 0 | 1 | N/A | N/A | N/A | 1 | N/A | N/A |
| 0 | 0 | 1 | 1 | N/A | N/A | N/A | 1 | N/A | N/A |
| 0 | 1 | 1 | 1 | N/A | N/A | N/A | 1 | N/A | N/A |
| 1 | 1 | 1 | 1 | N/A | N/A | N/A | 1 | N/A | N/A |

| Thermometer code | | | | | Binary code | | | | Decimal |
|---|---|---|---|---|---|---|---|---|---|
| O₄ | O₃ | O₂ | O₁ | O₀ | B₃ | B₂ | B₁ | B₀ | value |
| N/A | 0 | 0 | 0 | 0 | 0 | 0 | 0 | 0 | 0 |
| N/A | 0 | 0 | 0 | 1 | 0 | 0 | 0 | 1 | 1 |
| N/A | 0 | 0 | 1 | 1 | 0 | 0 | 1 | 0 | 2 |
| N/A | 0 | 1 | 1 | 1 | 0 | 0 | 1 | 1 | 3 |
| 0 | 1 | N/A | N/A | N/A | 0 | 1 | 0 | 0 | 4 |
| 1 | 1 | N/A | N/A | N/A | 0 | 1 | 0 | 1 | 5 |
| 1 | 1 | N/A | N/A | N/A | 0 | 1 | 1 | 0 | 6 |
| 1 | 1 | N/A | N/A | N/A | 0 | 1 | 1 | 1 | 7 |
| N/A | N/A | N/A | N/A | N/A | 1 | 0 | 0 | 0 | 8 |
| N/A | N/A | N/A | N/A | N/A | 1 | 0 | 0 | 1 | 9 |
| N/A | N/A | N/A | N/A | N/A | 1 | 0 | 1 | 0 | 10 |
| N/A | N/A | N/A | N/A | N/A | 1 | 0 | 1 | 1 | 11 |
| N/A | N/A | N/A | N/A | N/A | 1 | 1 | 0 | 0 | 12 |
| N/A | N/A | N/A | N/A | N/A | 1 | 1 | 0 | 1 | 13 |
| N/A | N/A | N/A | N/A | N/A | 1 | 1 | 1 | 0 | 14 |
| N/A | N/A | N/A | N/A | N/A | 1 | 1 | 1 | 1 | 15 |

The inverter 210, NAND gate 220 and NAND gate 230 of the latch logic circuit 200 perform logical operations to convert the bits O₀˜O₁₄ of the thermometer code into the bits B₀˜B₃ of the binary code, as shown in Table 3-2.

TABLE 3-2

| Cycle | | | | |
|---|---|---|---|---|
| MSB1 | Q2 = | Q1 = | | |
| | (Q2)NAND(DL) | (Q1)NAND(DL) | | |
| MSB2 | Q1 = | | | |
| | (Q1) NAND(DL) | | | |
| LSB1 | L3 = | | | |
| | DL | | | |
| LSB2 | L3 = | CDL = | L1 = | L2 = |
| | (L3) NAND(DL) | L3 | INV(DL) | DL |
| LSB3 | L3 = | L3 = | CDL = | |
| | DL | (L3) NAND (DL) | (CDL)NAND(L3) | |

Moreover, FIG. 7B illustrates an adjustment method of the initial charge amount Q_{SEN} of the node SEN when the latch logic circuit 200 processes the bits O₀˜O₁₄ to generate the bits B₀˜B₃. Referring to both Table 3-2 and FIG. 7B, firstly, performing the following operations in the operating period “Cycle MSB1”: (1) Pre-setting the initial charge amount Q_{SEN} of the node SEN as an equivalent charge amount 2.5Q. (2) The storage data of the latch DL and the storage data of the latch element Q2 are performed with a “NAND” operation, and the operation result is stored in the latch element Q2. (3) The storage data of the latch DL and the storage data of the latch element Q1 are performed with a “NAND” operation, and the operation result is stored in the latch element Q1.

If the latch element Q2 stores a logic value “1”, an “NAND” operation are performed on the storage data in the latch DL and the storage data in the latch element Q1 in the subsequent operating period “Cycle MSB2”, and the operation result is stored in latch element Q1. Accordingly, the initial charge amount Q_{SEN} of the node SEN is set as an equivalent charge amount 3.5Q. On the other hand, if the latch element Q2 stores a logic value “0”, the initial charge amount Q_{SEN} of the node SEN is set as an equivalent charge amount 1.5Q in the subsequent operating period “Cycle MSB2”.

Then, in the subsequent operating period “Cycle LSB1”, the storage data of the latch DL is transferred to the latch L3. If the current initial charge amount Q_{SEN} is the equivalent charge amount 3.5Q, and the latch element Q1 stores a logic value “1”, the initial charge amount Q_{SEN} is set as the equivalent charge amount 4Q. If the latch element Q1 stores a logic value “0”, the initial charge amount Q_{SEN} is set as the equivalent charge amount 3Q. On the other hand, if the current initial charge amount Q_{SEN} is the equivalent charge amount 1.5Q, and the latch element Q1 stores a logic value “1”, the initial charge amount Q_{SEN} is set as the equivalent charge amount 2Q. If the latch element Q1 stores a logic value “0”, the initial charge amount Q_{SEN} is set as the equivalent charge amount 1Q.

Then, the current initial charge amount Q_{SEN} remains unchanged in the subsequent operating period “Cycle LSB2”. For example, if the current initial charge amount Q_{SEN} is the equivalent charge amount 4Q, it is maintained as the equivalent charge amount 4Q. If the current initial charge amount Q_{SEN} is the equivalent charge amount 3Q, it is maintained as the equivalent charge amount 3Q, etc. More specifically, the following operations are performed in the operating period “Cycle LSB2”: (1) The bit O₁ obtained at time point t1 is stored in the latch DL. (2) The bit O₁ stored in the latch DL and the bit O₂ stored in the latch L3 are performed with a “NAND” operation by the NAND gate 220, and the operation result is stored in the latch L3. (3) The inverter 210 inverts the bit O₁ stored in the latch DL to O̅₁̅ and stores it in the latch L1. (4) The bit O₁ stored in the latch DL is transferred to the latch L2. (5) The storage data of latch L3 is transferred to latch CDL.

Then, the current initial charge amount Q_{SEN} remains unchanged in the subsequent operating period “Cycle LSB3”. The following operations are performed: (1) The bit O₁ stored in the latch DL is transferred to the latch L3. (2) The bit O₀ obtained at time point t1 is stored in the latch DL. (3) The bit O₀ stored in the latch DL and the bit 01 stored in the latch L3 are performed with a “NAND” operation by the NAND gate 220, and the operation result is stored in the latch L3. (4) The storage data of the latch CDL and the storage data of the latch L3 are performed with a “NAND” operation by the NAND gate 230, and the operation result is stored in the latch CDL.

FIG. 7C is a schematic diagram illustrating the time consumption of performing input quantization at three time points according to the embodiment of FIG. 7A. After the bit line BL performs an analog summing operation (denoted as “analog sum” in FIG. 7A), the latch logic circuit 200 then generates the bit B₂, and concurrently the sensing circuit 100 performs input quantization at time point t2 to generate the bit O₂. Then, input quantization is performed at time point t1 to generate bit O₁. After the input quantization of bit O₁ is completed, the latch logic circuit 200 then generates bit B₁, and the sensing circuit 100 performs input quantization at time point t0 to generate bit O₀. After the input quantization of bit O₀ is completed, the latch logic circuit 200 then generates bit B₀, and concurrently the bit line BL performs the next analog summing operation (denoted as “next analog sum” in FIG. 7A). In this embodiment, the input quantization(s) of three bits O₂, O₁, and O₀ are performed at three time points, and three times of “BL toggling” have to be performed. The input quantization(s) of three bits O₂, O₁ and O₀ may consume a processing time tQTZ1.

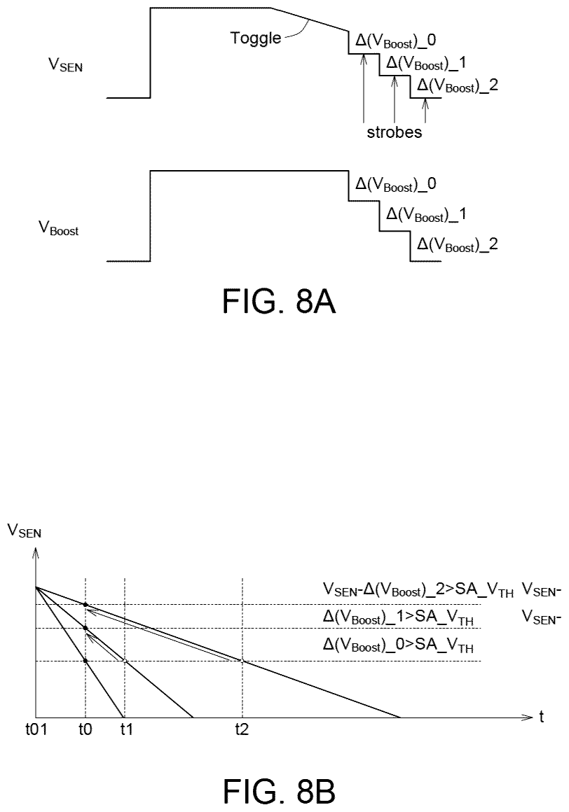

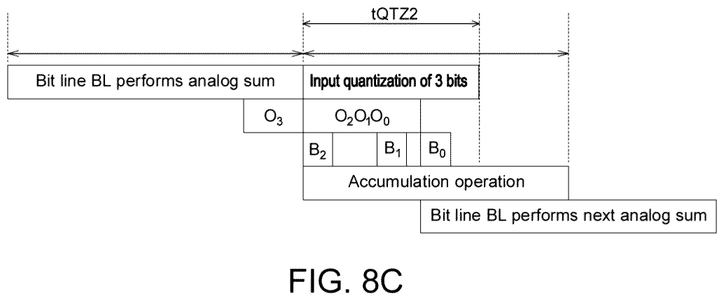

The analog-to-digital conversion device 1002 may also utilize a faster input quantization mechanism when performing analog-to-digital conversion of four bits. FIG. 8A is a schematic diagram illustrating the changes of the voltage V_{SEN} of the node SEN and the voltage V_{Boost} of the node Boost when the analog-to-digital conversion device 1002 of FIG. 6 utilizes a faster input quantization mechanism. As shown in FIG. 8A, the voltage V_{Boost} of node Boost gradually decreases in steps. The steps of decreasing are: voltage difference Δ(V_{Boost})_0, voltage difference Δ(V_{Boost})_1 and voltage difference Δ(V_{Boost})_2, which may be referred to as “step-voltage-difference”. Concurrently, the voltage V_{SEN} of the node SEN also gradually decreases according to the above-mentioned voltage difference Δ(V_{Boost})_0, voltage difference Δ(V_{Boost})_1 and voltage difference Δ(V_{Boost})_2.

FIG. 8B is a schematic diagram illustrating the change of the voltage V_{SEN} of the node SEN with respect to time t when the analog-to-digital conversion device 1002 of FIG. 6 utilizes the faster input quantization mechanism. Compared with the embodiment in FIG. 7A which generates the two bits B₁ and B₀ of the LSB at time points t2, t1 and t0 respectively, the embodiment in FIG. 8B executes the input quantization mechanism at a single time point t0 to generate the two bits B₁ and B₀ of the LSB, which may reduce the time required for input quantization. At time point t0, input quantization is performed based on the three voltage differences Δ(V_{Boost})_0, A (V_{Boost})_1 and Δ(V_{Boost})_2 of the node Boost shown in FIG. 8B.

At time point t0, the sensing circuit 100 determines whether a difference value between the voltage V_{SEN} of the node SEN and the voltage difference Δ(V_{Boost})_0 for the node Boost is greater than the threshold voltage SA_V_{TH} of the sensing amplifier 110. When the difference value between the voltage V_{SEN} and the voltage difference Δ(V_{Boost})_0 is greater than the threshold voltage SA_V_{TH} (as shown in equation (4-1)), the bit O₀ generated by the sensing circuit 100 is a logic value “0”.

$${V}_{SEN} - Δ ( {V}_{Boost} ) \_ 0 > {SA\_V}_{TH} \qquad ( 4 - 1 )$$

On the other hand, when the difference value between the voltage V_{SEN} and the voltage difference Δ(V_{Boost})_0 is less than the threshold voltage SA_V_{TH} (as shown in equation (4-2)), the bit O₀ generated by the sensing circuit 100 is a logic value “1”.

$${V}_{SEN} - Δ ( {V}_{Boost} ) \_ 0 < {SA\_V}_{TH} \qquad ( 4 - 2 )$$

Similarly, at time point t0, when the difference value between the voltage V_{SEN} and the voltage difference Δ(V_{Boost})_1 is greater than or less than the threshold voltage SA_V_{TH}, the bit O₁ generated by the sensing circuit 100 is a logic value “0” or a logic value “1”. At time point t0, when the difference value between the voltage V_{SEN} and the voltage difference Δ(V_{Boost})_2 is greater than or less than the threshold voltage SA_V_{TH}, the bit O₂ generated by the sensing circuit 100 is a logic value “0” or a logic value “1”.

Furthermore, the bits B₂ and B₃ of the MSB are generated utilizing the mechanism of SAR. When bit B₂ is a logic value “0”, the initial charge amount Q_{SEN} of the node SEN is set as the equivalent charge amount Q by the latch elements Q2 and Q1. When bit B₂ is a logic value “1”, the initial charge amount Q_{SEN} is set as the equivalent charge amount 2Q.

FIG. 8C is a schematic diagram illustrating the time consumption of performing input quantization at a single time point according to the embodiment of FIG. 8B. Compared with the embodiment of FIG. 7C, the input quantization of the three bits O₂, O₁, and O₀ in this embodiment may be performed at the same time point, hence the processing time tQTZ2 for the input quantization of the three bits O₂, O₁, and O₀ may be reduced. Such as, the processing time tQTZ2 for the input quantization in the example of FIG. 8C is less than the processing time tQTZ1 for the input quantization in the example of FIG. 7C. Furthermore, the processing time for the input quantization of the three bits O₂, O₁, and O₀ may be overlapped with the processing time for the latch logic circuit 200 to generate the bit B₁. During the process of the input quantization of the three bits O₂, O₁, and O₀ in this embodiment, in addition to two times of strobe operations performed by the sensing amplifier 110, the sensing circuit 100 only needs to perform one time of “BL toggling”, hence operation time may be saved.

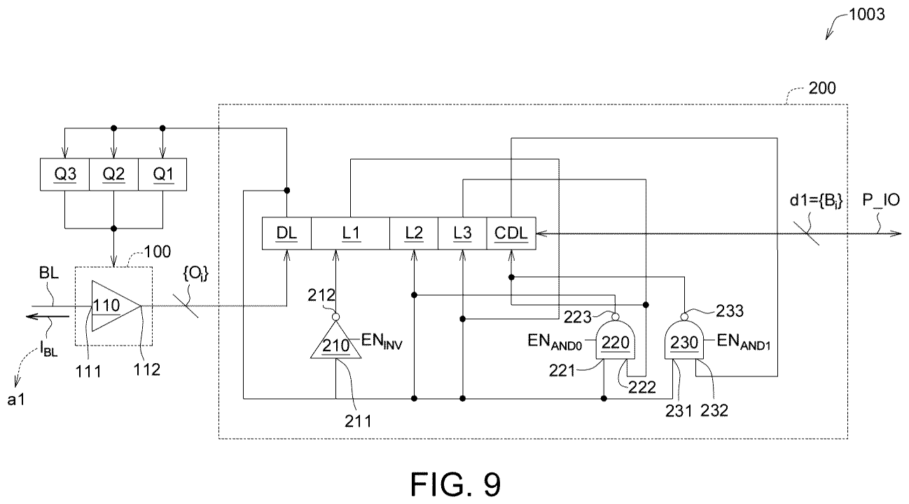

FIG. 9 is a circuit diagram of an analog-to-digital conversion device 1003 according to yet another embodiment of the present disclosure. The analog-to-digital conversion device 1003 of this embodiment is used to perform analog-to-digital conversion of five bits (i.e., the bit width is equal to “five”). The generated digital value d1 may include five bits B₄, B₃, B₂, B₁ and B₀. Compared with the analog-to-digital conversion device 1002 of FIG. 6, the analog-to-digital conversion device 1002 of this embodiment further includes another latch element Q3. The latch elements Q1˜Q3 are used to set the initial charge amount Q_{SEN} of the node SEN of the sensing circuit 100.

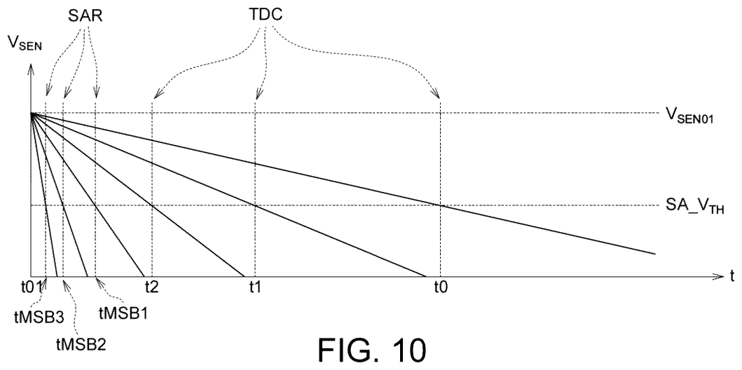

FIG. 10 is a schematic diagram illustrating the change of the voltage V_{SEN} of the node SEN with respect to time t when the analog-to-digital conversion device 1003 of FIG. 9 performs analog-to-digital conversion of five bits. Compared with the embodiment of FIG. 7A, the sensing circuit 100 of this embodiment further sets a time point tMSB3 for generating the bit B₄ of the MSB.

TABLE 4-1

| Cycle | | | | |
|---|---|---|---|---|
| MSB1 | Q3 = | Q2 = | | |
| | (Q3)NAND(DL) | (Q2) NAND(DL) | | |
| MSB2 | Q2 = | Q1 = | | |
| | (Q2)NAND(DL) | (Q1) NAND(DL) | | |
| MSB3 | Q1 = | | | |
| | (Q1) NAND (DL) | | | |
| LSB1 | L3 = | | | |
| | DL | | | |
| LSB2 | L3 = | CDL = | L1 = | L2 = |
| | (L3) NAND(DL) | L3 | INV(DL) | DL |
| LSB3 | L3 = | L3 = | CDL = | |
| | DL | (L3) NAND(DL) | (CDL)NAND(L3) | |

As shown in Table 4-1, the inverter 210, NAND gate 220 and NAND gate 230 of the latch logic circuit 200 perform logical operations to generate bits B₀˜B₄ of the binary code. The operating manner of the latch logic circuit 200 in this embodiment is similar to the embodiment in Table 3-2. The difference between these two embodiments is that, in Table 4-1, the following operations are performed in the operating period “Cycle MSB1”: (1) The initial charge amount Q_{SEN} of the node SEN is pre-set as an equivalent charge amount 4.5Q. (2) The storage data in the latch DL and the storage data in the latch element Q3 are performed with an “NAND” operation, and the operation result is stored in the latch element Q3. (3) The storage data in the latch DL and the storage data in the latch element Q2 are performed with an “NAND” operation, and the operation result is stored in the latch element Q2.

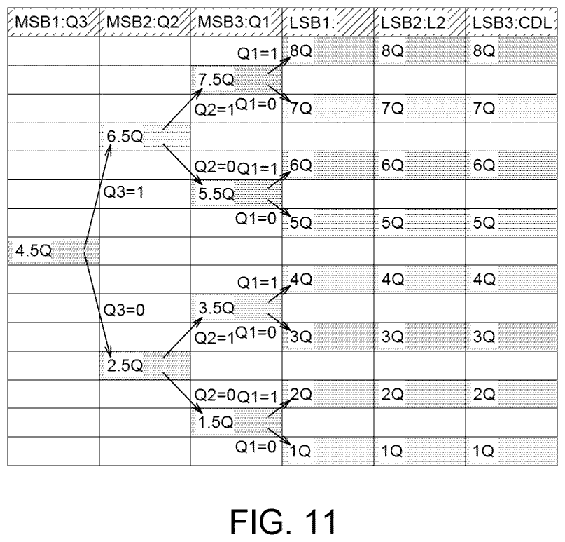

FIG. 11 illustrates an adjustment method of the initial charge amount Q_{SEN} of the node SEN when the latch logic circuit 200 of this embodiment processes the bits O₀˜O₁₄ to generate the bits B₀˜B₃. Referring to FIG. 11, the initial charge amount Q_{SEN} of the node SEN is pre-set as an equivalent charge amount 4.5Q.

Then, in the subsequent operating period “Cycle MSB2”, if the latch element Q3 stores the logic value “1”, the initial charge amount Q_{SEN} is adjusted as an equivalent charge amount 6.5Q. If the latch element Q3 stores the logic value “0”, the initial charge amount Q_{SEN} is adjusted as an equivalent charge amount 2.5Q.

Then, in the subsequent operating period “Cycle MSB3”, if the initial charge amount Q_{SEN} is an equivalent charge amount 6.5Q, and the latch element Q2 stores the logic value “1”, then the initial charge amount Q_{SEN} is adjusted as an equivalent charge amount 7.5Q. If the latch element Q2 stores the logic value “0”, the initial charge amount Q_{SEN} is adjusted as an equivalent charge amount 5.5Q.

On the other hand, if the initial charge amount Q_{SEN} is an equivalent charge amount 2.5Q and the latch element Q2 stores a logic value “1”, the initial charge amount Q_{SEN} is adjusted as the equivalent charge amount 3.5Q. If the latch element Q2 stores the logic value “0”, the initial charge amount Q_{SEN} is adjusted as an equivalent charge amount 1.5Q.

Then, in the subsequent operating period “Cycle LSB1”, if the initial charge amount Q_{SEN} is an equivalent charge amount 7.5Q, and the latch element Q1 stores the logic value “1”, then the initial charge amount Q_{SEN} is adjusted as an equivalent charge amount 8Q. If the latch element Q1 stores the logic value “0”, the initial charge amount Q_{SEN} is adjusted as an equivalent charge amount 7Q. Furthermore, if the initial charge amount Q_{SEN} is an equivalent charge amount 5.5Q and the latch element Q1 stores a logic value “1”, it is adjusted as an equivalent charge amount 6Q. If the latch element Q1 stores a logic value “0”, it is adjusted as an equivalent charge amount of 5Q. In addition, if the initial charge amount Q_{SEN} is an equivalent charge amount 3.5Q and the latch element Q1 stores a logic value “1”, it is adjusted as the equivalent charge amount 4Q. If the latch element Q1 stores the logic value “0”, it is adjusted as the equivalent charge amount 3Q. Furthermore, if the initial charge amount Q_{SEN} is an equivalent charge amount 1.5Q and the latch element Q1 stores a logic value “1”, it is adjusted as an equivalent charge amount 2Q. If the latch element Q1 stores the logic value “0”, it is adjusted as an equivalent charge amount 1Q.

In summary, the analog-to-digital conversion devices of various embodiments of the present disclosure may be adapted to the architecture of a standard page buffer of the memory array (especially for the NAND flash memory array), and therefore may achieve high operating bandwidth, and have lower energy consumption.

It will be apparent to those skilled in the art that various modifications and variations may be made to the disclosed embodiments. It is intended that the specification and examples be considered as exemplars only, with a true scope of the disclosure being indicated by the following claims and their equivalents.

What is claimed is:

1. An analog-to-digital conversion device, comprising:
a sensing circuit, coupled to a bit line of a memory array, and used to sense a current in the bit line to generate a bit-sequence, the bit-sequence has a form of a thermometer code to represent an analog value; and
a latch logic circuit, including a plurality of latches and a plurality of logic circuits to form a page buffer of the memory array, and used to generate a bit-set according to the bit-sequence, the bit-set has a form of a binary code to represent a digital value;
wherein, the latches and the logic circuits perform a conversion process to convert the bit-sequence into the bit-set, and the conversion process has a bit width.

2. The analog-to-digital conversion device according to claim 1, wherein the logic circuits of the latch logic circuit include an inverter and two NAND gates, and the inverter and the NAND gates execute a truth value conversion for the thermometer code and the binary code.

3. The analog-to-digital conversion device according to claim 1, wherein the sensing circuit comprising:
a sensing amplifier, having an input end coupled to the bit line, the input end has a first node, and the first node has a first node voltage;
wherein, the sensing circuit generates the bit-sequence according to the first node voltage and a threshold voltage of the sensing amplifier.

4. The analog-to-digital conversion device according to claim 3, wherein one of the latches of the latch logic circuit is coupled to an output end of the sensing amplifier to receive the bit-sequence, and another one of the latches is coupled to a data input/output path to transmit the bit-set.

5. The analog-to-digital conversion device according to claim 3, wherein when the first node voltage is greater than or less than the threshold voltage, the bit-sequence has a logic value “0” or a logic value “1”.

6. The analog-to-digital conversion device according to claim 3, wherein the sensing circuit generates the bit-sequence according to a plurality of sensing time points at which the first node voltage decreases to the threshold voltage.

7. The analog-to-digital conversion device according to claim 6, wherein when the bit width of the conversion process is equal to two, the sensing circuit generates the bit-sequence according to a first time point, a second time point and a third time point of the sensing time points.

8. The analog-to-digital conversion device according to claim 7, wherein the latch logic circuit generates two bits of least significant bits (LSB) of the bit-set by a time-to-digital conversion (TDC) mechanism according to the first time point, the second time point and the third time point.

9. The analog-to-digital conversion device according to claim 6, wherein when the bit width of the conversion process is greater than or equal to three, the sensing circuit generates one bit of the bit-sequence according to at least one fourth time point of the sensing time points.

10. The analog-to-digital conversion device according to claim 9, wherein the latch logic circuit generates at least one bit of most significant bits (MSB) of the bit-set by a successive-approximation register (SAR) mechanism according to the at least one fourth time point.

11. The analog-to-digital conversion device according to claim 3 further comprising:
at least one latch element, coupled to the sensing circuit, and used to set an initial charge amount of the first node.

12. The analog-to-digital conversion device according to claim 11, wherein when the at least one latch element stores a logic value “1” or a logic value “0”, the initial charge amount of the first node increases or decreases to an equivalent charge amount.

13. The analog-to-digital conversion device according to claim 11, wherein the number of the at least one latch element is equal to the bit width of the conversion process minus two.

14. The analog-to-digital conversion device according to claim 3, wherein the first node is coupled to a second node through a capacitor, the second node has a second node voltage, and the first node voltage and the second node voltage gradually decreases according to at least one step-voltage-difference.

15. The analog-to-digital conversion device according to claim 14, wherein the sensing circuit generates the bit-sequence according to a difference between the first node voltage and the at least one step-voltage-difference and the threshold voltage.

16. The analog-to-digital conversion device according to claim 15, wherein the sensing circuit generates the bit-sequence according to a sensing time point when the first node voltage decreases to the threshold voltage.
